(19) United States
(12) Patent Application Publication
(10) Pub. No.: US 2021/0184166 A1
(43) Pub. Date: Jun. 17, 2021

(54) ORGANIC LIGHT-EMITTING DIODE PANEL AND METHOD FOR FABRICATING THEREOF

(71) Applicant: WUHAN CHINA OPTOELECTRONICS SEMICONDUCTOR DISPLAY TECHNOLOGY CO., LTD., Wuhan (CN)

(72) Inventor: Lun SHANG, Wuhan (CN)

(73) Assignee: WUHAN CHINA OPTOELECTRONICS SEMICONDUCTOR DISPLAY TECHNOLOGY CO., LTD., Wuhan (CN)

(21) Appl. No.: 16/349,620

(22) PCT Filed: Jan. 15, 2019
(86) PCT No.: PCT/CN2019/071814

§ 371 Date: May 14, 2019

(30) Foreign Application Priority Data
Dec. 12, 2018 (CN) 201811517109.7

(51) Int. Cl. H01L 51/52; H01L 51/56; H01L 51/00; H01L 51/50

(52) U.S. Cl. CPC H01L 51/5253; H01L 51/56; H01L 51/5072; H01L 51/5056; H01L 51/0097

(57) ABSTRACT

An organic light-emitting diode (OLED) panel and a method for fabricating the OLED panel are provided. The method for fabricating the organic light-emitting diode panel includes providing a glass substrate, forming a metal layer on an edge of the glass substrate, forming a support layer on an inner side of the metal layer, providing a flexible substrate consisted of a thermoplastic polyurethane elastic rubber, attaching the flexible substrate fittingly to the glass substrate, heating the flexible substrate to secure the flexible substrate and the glass substrate together, forming an organic light-emitting diode component on the flexible substrate, forming a packaging layer on the organic light-emitting diode component, and separating the flexible substrate from the glass substrate.

### BACKGROUND OF INVENTION

### Field of Invention

The present invention relates to a field of flexible substrate display, and more particularly, to a flexible substrate used for an organic light-emitting diode (OLED) display device.

### Description of Prior Art

Organic light-emitting diode (OLED) display devices do not require backlight modules, and very thin organic material coating layers and glass substrates are used for the OLED display devices. The organic material coating layers are illuminated when an electric current passes through the organic material coating layers. Furthermore, OLED display screens are lighter and thinner than conventional liquid crystal display screens and have wide viewing angles, and can significantly save power.

OLED panels are required to prevent failures from occurring in a bending region, and the OLED panels are also required to have properties of flexibility, environmental friendliness, high expendability, and high stability. Currently, when flexible substrates of the OLED display devices undergo dynamic bending for many times, the flexible substrates are easily broken. Therefore, it is necessary to provide a flexible substrate to solve the problems existing in the prior art.

### SUMMARY OF INVENTION

Currently, when flexible substrates of the organic light-emitting diode (OLED) display devices undergo dynamic bending for many times, the flexible substrates are easily broken.

According to one embodiment of the present invention, a method for fabricating an organic light-emitting diode (OLED) panel are provided. The method comprises providing a glass substrate, providing a flexible substrate consisted of a thermoplastic polyurethane elastic rubber, attaching the flexible substrate fittingly to the glass substrate, heating the flexible substrate to secure the flexible substrate and the glass substrate together, forming an organic light-emitting diode component on the flexible substrate, forming a packaging layer on the organic light-emitting diode component, and separating the flexible substrate from the glass substrate.

In one embodiment of the present invention, the method further comprises forming a metal layer on an edge of the glass substrate and forming a support layer on an inner side of the metal layer.

In one embodiment of the present invention, the support layer comprises silicon nitride or silicon dioxide.

In one embodiment of the present invention, the metal layer comprises iron, zinc or chromium.

In one embodiment of the present invention, the flexible substrate comprises a first surface and a second surface opposite to the first surface, and the first surface and the second surface are coated with an ink.

In one embodiment of the present invention, the organic light-emitting diode component comprises an anode, an organic material layer, and a cathode, and the organic material layer is disposed between the anode and the cathode.

In one embodiment of the present invention, the organic material layer comprises a hole transport layer, an organic light-emitting layer, and an electron transport layer, and the organic light-emitting layer is disposed between the hole transport layer and the electron transport layer.

In one embodiment of the present invention, the hole transport layer is disposed between the anode and the organic light-emitting layer.

In one embodiment of the present invention, the electron transport layer is disposed between the organic light-emitting layer and the cathode.

In one embodiment of the present invention, the method further comprises coating a plastic polyurethane elastic rubber on a base plate and performing soft baking and cutting to form the flexible substrate.

According to another embodiment of the present invention, an organic light-emitting diode (OLED) panel comprises a flexible substrate consisted of a thermoplastic polyurethane elastic rubber, an organic light-emitting diode component disposed on the flexible substrate, and a packaging layer disposed on the organic light-emitting diode component.

In one embodiment of the present invention, the flexible substrate comprises a first surface and a second surface opposite to the first surface, and the first surface and the second surface are coated with an ink.

In one embodiment of the present invention, the organic light-emitting diode component comprises an anode, an organic material layer, and a cathode, and the organic material layer is disposed between the anode and the cathode.

In one embodiment of the present invention, the organic material layer comprises a hole transport layer, an organic light-emitting layer, and an electron transport layer, and the organic light-emitting layer is disposed between the hole transport layer and the electron transport layer.

In one embodiment of the present invention, the hole transport layer is disposed between the anode and the organic light-emitting layer.

In one embodiment of the present invention, the electron transport layer is disposed between the organic light-emitting layer and the cathode.

In one embodiment of the present invention, the method further comprises coating a plastic polyurethane elastic rubber on a base plate and performing soft baking and cutting to form the flexible substrate.

The OLED panels according to embodiments of the present invention panels are provided with good stability and expendability, and therefore failures occurred in the bending region can be avoided, so as to keep costs down.

### BRIEF DESCRIPTION OF DRAWINGS

FIG. 1 is a schematic side view of a flexible substrate attached fittingly to a glass substrate according to one embodiment of the present invention.

FIG. 2 is a schematic view of a first region and a second region of the flexible substrate according to one embodiment of the present invention.

FIG. 3 is a schematic view of a flexible substrate which is bent according to one embodiment of the present invention.

FIG. 4 is a schematic view of forming an organic light-emitting diode component on the flexible substrate according to one embodiment of the present invention.

### DETAILED DESCRIPTION OF PREFERRED EMBODIMENTS

In order to make the present invention more comprehensible, the preferred embodiments are described below in detail with reference to the accompanying drawings.

According to one embodiment of the present invention, a method for fabricating an organic light-emitting diode (OLED) panel is provided. The method for fabricating the organic light-emitting diode panel comprises providing a glass substrate, forming a metal layer on an edge of the glass substrate, forming a support layer on an inner side of the metal layer, providing a flexible substrate 20, attaching the flexible substrate 20 fittingly to the glass substrate, heating the flexible substrate 20 to secure the flexible substrate 20 and the glass substrate together, forming an organic light-emitting diode component 100 on the flexible substrate 20, forming a packaging layer (not shown) on the organic light-emitting diode component 100, and separating the flexible substrate and the glass substrate. In addition, the organic light-emitting diode component 100 comprises an anode 30, an organic material layer 101, and a cathode 70, and the organic material layer 101 is disposed between the anode 30 and the cathode 70. The organic material layer 101 comprises a hole transport layer 40, an organic light-emitting layer 50, and an electron transport layer 60.

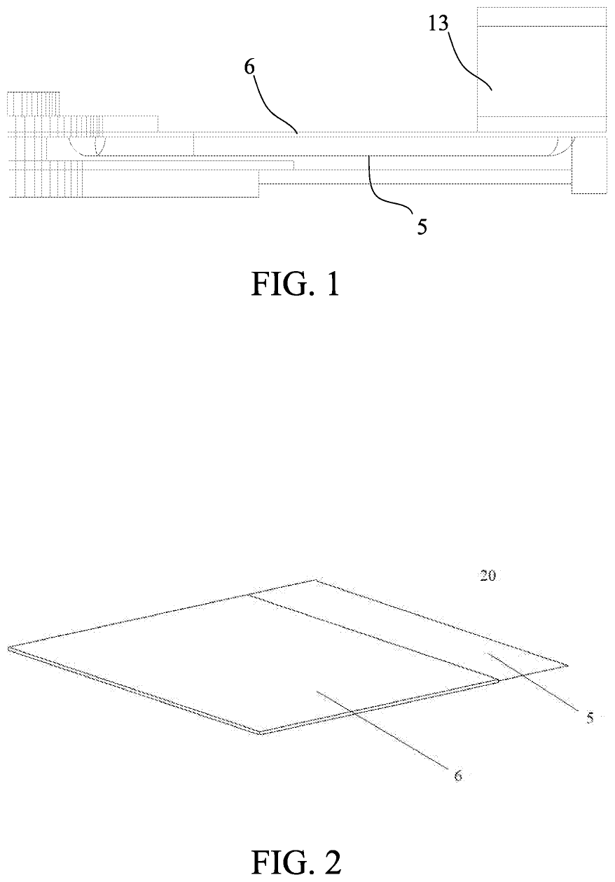

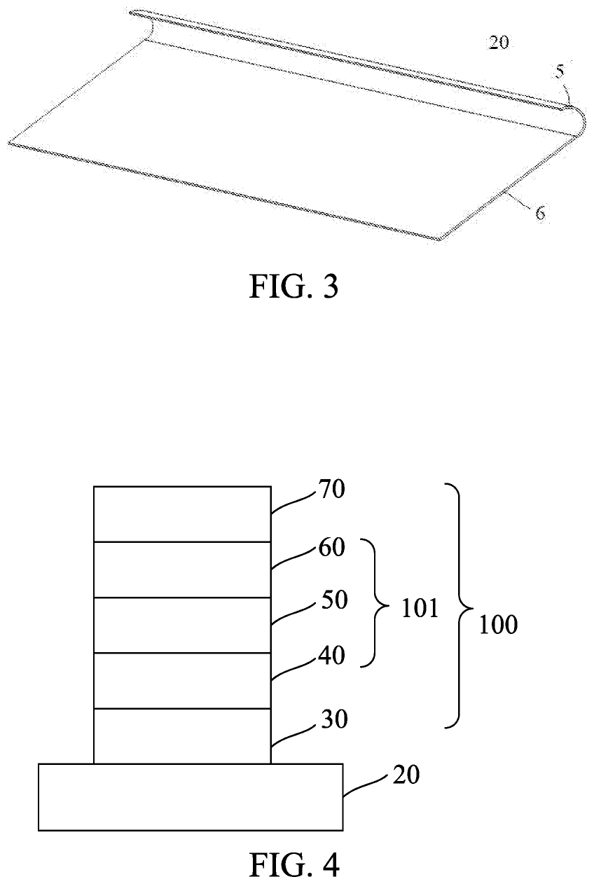

In detail, referring to FIG. 1 to FIG. 3, a side of the support layer disposed on the glass substrate, according to one embodiment of the present invention, is coated with a curing adhesive, and then the flexible substrate 20 is fittingly attached to the glass substrate. A first region 5 of the flexible substrate 20 is fittingly attached to the side of the support layer disposed on the glass substrate. A second region 6 of the flexible substrate 20 is fittingly attached to an upper surface of the support layer disposed on the glass substrate. In addition, an area of the first region 5 and an area of the second region 6 of the flexible substrate 20 can be appropriately adjusted as needed. When the flexible substrate 20 is fittingly attached to the glass substrate, the fixing component 13 is attached for fixing. It should be noted that the flexible substrate 20, according to the embodiment of the present invention, is consisted of a thermoplastic polyurethane elastic rubber. The flexible substrate 20 has good stability and expendability and can also reduce the probability of bending failure of the flexible substrate.

Specifically, the flexible substrate 20 is fabricated through coating the thermoplastic polyurethane elastic rubber on a base plate and performing soft baking and cutting to form the flexible substrate 20 consisted of the thermoplastic polyurethane elastic rubber. The flexible substrate 20 comprises a first surface and a second surface opposite to the first surface, and the first surface and the second surface are coated with ink. A thickness of the flexible substrate 20 is equal or less than 10 μm. The support layer comprises silicon nitride or silicon dioxide. The metal layer comprises iron, zinc or chromium.

After the flexible substrate 20 is fittingly attached to the glass substrate, the organic light-emitting diode component 100 is formed on the flexible substrate 20. A packaging layer (not shown) is formed on the organic light-emitting diode component 100 and then the flexible substrate 20 is separated from the glass substrate. Referring to FIG. 4, the organic light-emitting diode component 100 comprises the anode 30, the organic material layer 101, and the cathode 70, and the organic material layer 101 is disposed between the anode 30 and the cathode 70. The organic material layer 101 comprises the hole transport layer 40 disposed between the anode 30 and the cathode 70, the organic light-emitting layer 50 disposed between the hole transport layer 40 and the electron transport layer 60, and the electron transport layer 60 disposed between the organic light-emitting layer 50 and the cathode 70.

According to another embodiment of the present invention, an organic light-emitting diode (OLED) panel is provided. The organic light-emitting diode panel comprises a flexible substrate consisted of a thermoplastic polyurethane elastic rubber, an organic light-emitting diode component 100 disposed on the flexible substrate 20, and a packaging layer disposed on the organic light-emitting diode component 100.

The OLED panels, according to embodiments of the present invention panels, are provided with good stability and expendability, and therefore failures occurred in the bending region can be avoided, so as to keep costs down.

In the above, the present application has been described in the above preferred embodiments, but the preferred embodiments are not intended to limit the scope of the invention, and a person skilled in the art may make various modifications without departing from the spirit and scope of the application. The scope of the present application is determined by claims.

What is claimed is:

1. A method for fabricating an organic light-emitting diode (OLED) panel, comprising:
providing a glass substrate
providing a flexible substrate, wherein the flexible substrate is consisted of a thermoplastic polyurethane elastic rubber;
attaching the flexible substrate fittingly to the glass substrate;
heating the flexible substrate to secure the flexible substrate and the glass substrate together;
forming an organic light-emitting diode component on the flexible substrate;
forming a packaging layer on the organic light-emitting diode component; and
separating the flexible substrate from the glass substrate.

2. The method for fabricating the OLED panel according to claim 1, further comprising forming a metal layer on an edge of the glass substrate and forming a support layer on an inner side of the metal layer.

3. The method for fabricating the OLED panel according to claim 2, wherein the support layer comprises silicon nitride or silicon dioxide.

4. The method for fabricating the OLED panel according to claim 2, wherein the metal layer comprises iron, zinc or chromium.

5. The method for fabricating the OLED panel according to claim 1, wherein the flexible substrate comprises a first surface and a second surface opposite to the first surface, and the first surface and the second surface are coated with ink.

6. The method for fabricating the OLED panel according to claim 1, wherein the organic light-emitting diode component comprises an anode, an organic material layer, and a cathode, and the organic material layer is disposed between the anode and the cathode.

7. The method for fabricating the OLED panel according to claim 6, wherein the organic material layer comprises a hole transport layer, an organic light-emitting layer, and an electron transport layer, and the organic light-emitting layer is disposed between the hole transport layer and the electron transport layer.

8. The method for fabricating the OLED panel according to claim 7, wherein the hole transport layer is disposed between the anode and the organic light-emitting layer.

9. The method for fabricating the OLED panel according to claim 7, wherein the electron transport layer is disposed between the organic light-emitting layer and the cathode.

10. The method for fabricating the OLED panel according to claim 1, further comprising coating a plastic polyurethane elastic rubber on a base plate and performing soft baking and cutting to form the flexible substrate.

11. An organic light-emitting diode (OLED) panel, comprising:
a flexible substrate, wherein the flexible substrate is consisted of a thermoplastic polyurethane elastic rubber;
an organic light-emitting diode component disposed on the flexible substrate; and
a packaging layer disposed on the organic light-emitting diode component.

12. The OLED panel according to claim 11, wherein the flexible substrate comprises a first surface and a second surface opposite to the first surface, and the first surface and the second surface are coated with ink.

13. The OLED panel according to claim 11, wherein the organic light-emitting diode component comprises an anode, an organic material layer, and a cathode, and the organic material layer is disposed between the anode and the cathode.

14. The OLED panel according to claim 13, wherein the organic material layer comprises a hole transport layer, an organic light-emitting layer, and an electron transport layer, and the organic light-emitting layer is disposed between the hole transport layer and the electron transport layer.

15. The OLED panel according to claim 14, wherein the hole transport layer is disposed between the anode and the organic light-emitting layer.

16. The OLED panel according to claim 14, wherein the electron transport layer is disposed between the organic light-emitting layer and the cathode.

17. The OLED panel according to claim 11, wherein the method further comprises coating a plastic polyurethane elastic rubber on a base plate and performing soft baking and cutting to form the flexible substrate.
